(19) United States
(12) Patent Application Publication
(10) Pub. No.: US 2014/0008819 A1
(43) Pub. Date: Jan. 9, 2014

(54) SUBSTRATE STRUCTURE, SEMICONDUCTOR PACKAGE AND METHODS OF FABRICATING THE SAME

(71) Applicant: SILICONWARE PRECISION INDUSTRIES CO., LTD., Taichung Hsien (TW)

(72) Inventors: Chien-Feng Chan, Taichung Hsien (TW); Chun-Tang Lin, Taichung Hsien (TW); Yi-Che Lai, Taichung Hsien (TW)

(73) Assignee: SILICONWARE PRECISION INDUSTRIES CO., LTD., Taichung Hsien (TW)

(21) Appl. No.: 13/660,249

(22) Filed: Oct. 25, 2012

(30) Foreign Application Priority Data
Jul. 9, 2012 (TW) 101124581

(51) Int. Cl. H01L 23/488; H01L 21/50; B32B 37/12; H01L 23/12

(52) U.S. Cl. 257/783; 257/798; 438/106; 156/60; 257/E23.023; 257/E23.003; 257/E21.567; 257/E21.499

(57) ABSTRACT

A substrate structure is provided, including a substrate and a strengthening member bonded to a surface of the substrate. The strengthening member has a CTE (Coefficient of Thermal Expansion) less than that of the substrate so as to effectively prevent warpage from occurring to the substrate structure.

### BACKGROUND OF THE INVENTION

1. Field of the Invention

The present invention relates to substrate structures, semiconductor packages and methods of fabricating the same, and, more particularly, to a substrate structure and a semiconductor package having an interposer, and methods of fabricating the same.

2. Description of Related Art

In order to meet the trends of miniaturization, multi-function, high electrical performance and high operational speed of electronic products, semiconductor packages are required to have small size, high performance, integrated function and high speed.

FIG. 1 is a cross-sectional view of a semiconductor package fabricated by a through silicon interposer technique according to the conventional technology. A plurality of through holes 100 are formed in a silicon substrate 10 and filled with a conductive material 101, and a circuit layer (not shown) is formed on the upper and the lower surfaces of the silicon substrate 10, thereby forming a through silicon interposer 1. The through silicon interposer 1 is disposed on an upper surface of a packaging substrate 11, and a semiconductor chip 12 is disposed on the through silicon interposer 1. A plurality of solder balls 13 are disposed on a lower surface of the packaging substrate 11.

In such a configuration, I/O pins of a plurality of semiconductor chips 12 can be integrated via the through silicon interposer 1.

However, coefficient of thermal expansion (CTE) mismatch exists between the semiconductor chips 12 which have a CTE of approximately 3 ppm/and the packaging substrate 11 which has a CTE of approximately 18 ppm/. As such, warpage can easily occur to the overall structure so as to lead to poor or non-wetting conductive elements 14 between the semiconductor chips 12 and the packaging substrate 11, thus reducing the product reliability. Although the through silicon interposer 1 is designed to have a CTE between the semiconductor chips 12 and the packaging substrate 11, the problem of CTE mismatch cannot be completely overcome.

### SUMMARY OF THE INVENTION

The present invention provides a substrate structure, which comprises: a substrate having a first surface and a second surface opposite to the first surface; and a strengthening member bonded to the second surface of the substrate, wherein the strengthening member has a CTE (Coefficient of Thermal Expansion) less than that of the substrate.

The present invention further provides a semiconductor package, which comprises: a substrate having a first surface and a second surface opposite to the first surface; a strengthening member bonded to the second surface of the substrate, wherein the strengthening member has a CTE less than that of the substrate; an interposer disposed on the first surface of the substrate; and a semiconductor chip disposed on the interposer.

The present invention further provides a method of fabricating a substrate structure, which comprises: providing a substrate having a first surface and a second surface opposite to the first surface; and bonding a strengthening member to the second surface of the substrate, wherein the strengthening member has a CTE less than that of the substrate.

The present invention further provides a method of fabricating a semiconductor package, which comprises: providing a substrate having a first surface and a second surface opposite to the first surface and a strengthening member bonded to the second surface of the substrate, wherein the strengthening member has a CTE less than that of the substrate; and disposing a semiconductor element on the first surface of the substrate and electrically connecting the semiconductor element and the substrate.

According to the present invention, a strengthening member and a semiconductor chip are disposed on opposite sides of a substrate, respectively, to form a sandwich structure and the CTEs of the strengthening member and the semiconductor chip are less than that of the substrate, thereby effectively preventing warpage from occurring to the semiconductor package.

### BRIEF DESCRIPTION OF DRAWINGS

FIG. 1 is a cross-sectional view of a conventional semiconductor package; and

FIGS. 2A to 2E are cross-sectional views showing a substrate structure, a semiconductor package and methods of fabricating the same according to the present invention, wherein FIGS. 2B′ and 2B″ show different embodiments of FIG. 2B.

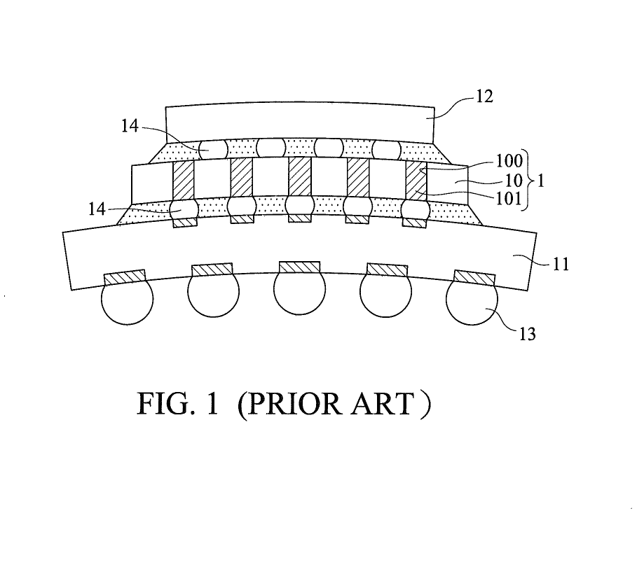

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that the drawings are only for illustrative purposes and not intended to limit the present invention. Meanwhile, terms such as “upper”, “lower”, “on” etc. are only used as a matter of descriptive convenience and not intended to have any other significance or provide limitations for the present invention.

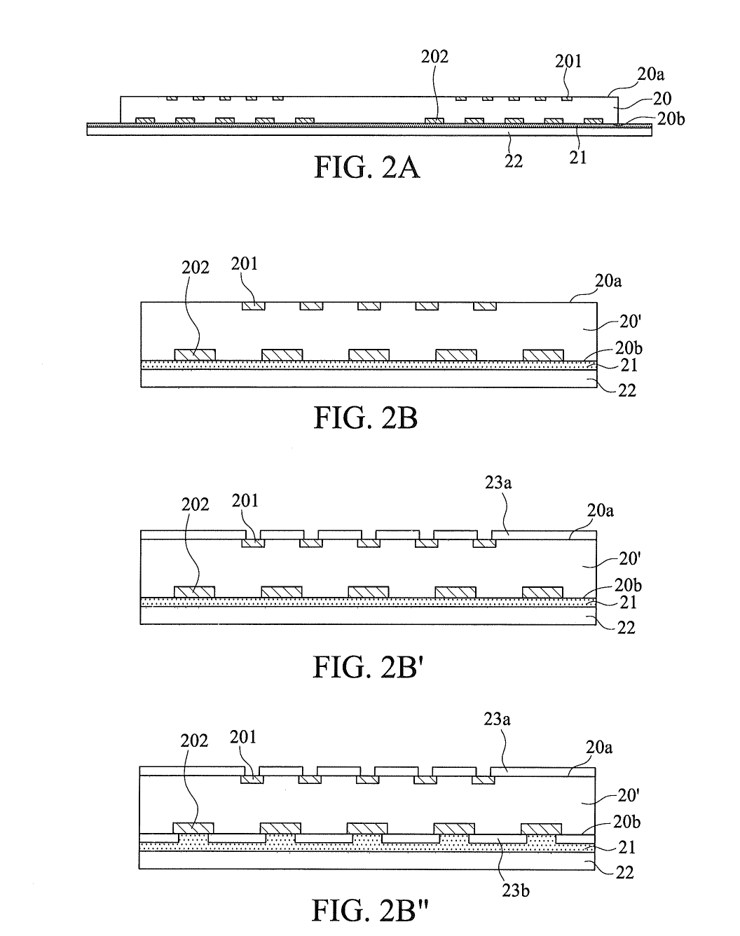

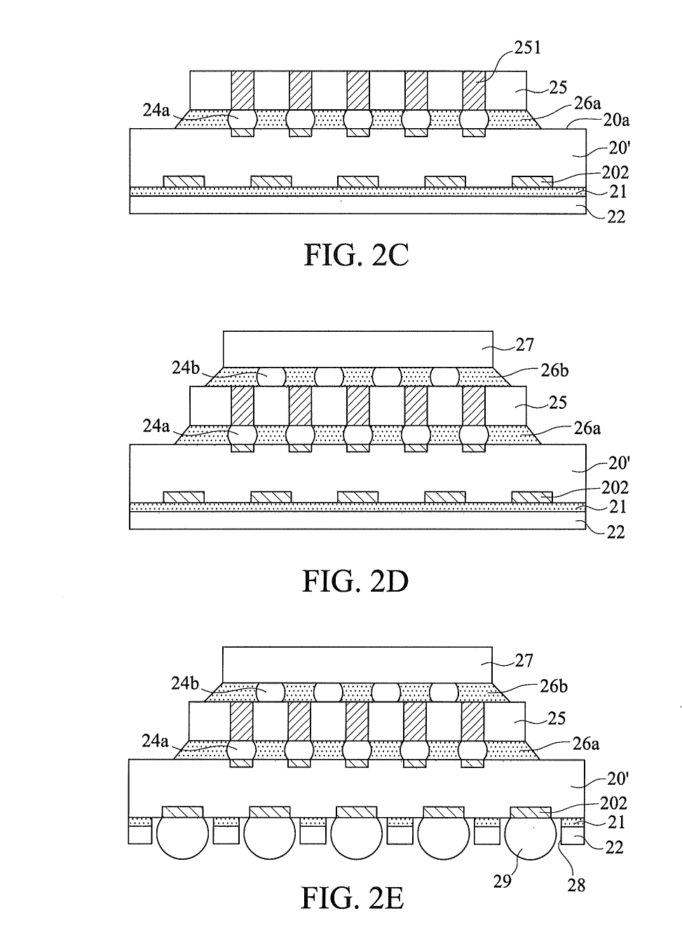

FIGS. 2A to 2E are cross-sectional views showing a substrate structure, a semiconductor package and methods of fabricating the same according to the present invention. FIGS. 2B′ and 2B″ show different embodiments of FIG. 2B.

Referring to FIG. 2A, a substrate 20 having a first surface 20a and a second surface 20b opposite to the first surface 20a is provided. The substrate 20 has a plurality of substrate units. The first surface 20a of the substrate 20 has a plurality of conductive pads 201, and the second surface 20b of the substrate 20 has a plurality of conductive pads 202. An adhesive layer 21 bonds a strengthening member 22 to the second surface 20b of the substrate 20. The strengthening member 22 has a CTE less than that of the substrate 20. Preferably, the strengthening member 22 has a CTE less than 10 ppm/and a thickness between 50 and 250 um. The strengthening member 22 is preferably made of graphite, graphene, polycrystalline silicon, monocrystalline silicon, glass, quartz or silicon dioxide. In an embodiment, the adhesive layer 21 is a high-temperature adhesive layer.

Referring to FIG. 2B, a singulation process is performed to form a plurality of substrate structures. Each of the substrate structures has a substrate 20′ and a strengthening member 22 bonded to a second surface 20b of the substrate 20′ through an adhesive layer 21. The strengthening member 22 has a CTE less than that of the substrate 20′. The substrate 20′ can be of a coreless type and made of ABF (Ajinomoto Build-up Film), BCB (Benzocyclobuthene), LCP (Liquid Crystal Polymer), PI (Polyimide), PPE (Polyphenylene ether), PTFE (Polytetrafluoroethylene), FR4, Fk5, BT (Bismaleimide Triazine) or aramide. In an embodiment, referring to FIG. 2B′, a first insulating layer 23a is formed on the first surface 20a of the substrate 20′. In another embodiment, referring to FIG. 2B″, a first insulating layer 23a is formed on the first surface 20a of the substrate 20′, a second insulating layer 23b is formed on the second surface 20b of the substrate 20′, and the adhesive layer 21 is formed on the second insulating layer 23b.

Referring to FIG. 2C, continued from FIG. 2B, an interposer 25 is disposed on the first surface 20a of the substrate 20′ through a plurality of first conductive elements 24a, and a first underfill 26a is filled between the interposer 25 and the substrate 20′. The interposer 25 has a plurality of conductive through holes 251. The first conductive elements 24a can be made of a solder material.

Referring to FIG. 2D, a semiconductor chip 27 is disposed on the interposer 25 through a plurality of second conductive elements 24b, and a second underfill 26b is filled between the interposer 25 and the semiconductor chip 27. The second conductive elements 24b can be made of a solder material.

Referring to FIG. 2E, portions of the adhesive layer 21 and the strengthening member 22 are removed to form openings 28 exposing the conductive pads 202. A plurality of conductive elements 29 such as solder balls are further disposed on the conductive pads 202.

The present invention further provides a substrate structure, which has: a substrate 20′ having a first surface 20a and a second surface 20b opposite to the first surface 20a; and a strengthening member 22 bonded to the second surface 20b of the substrate 20′ through an adhesive layer 21, wherein the strengthening member 22 has a CTE less than that of the substrate 20′.

The present invention further provides a semiconductor package, which has: a substrate 20′ having a first surface 20a and a second surface 20b opposite to the first surface 20a; a strengthening member 22 bonded to the second surface 20b of the substrate 20′ and having a CTE less than that of the substrate 20′; an interposer 25 disposed on the first surface 20a of the substrate 20′; and a semiconductor chip 27 disposed on the interposer 25.

In an embodiment, the strengthening member 22 has a CTE less than 10 ppm/and a thickness between 50 and 250 um, and is made of graphite, graphene, polycrystalline silicon, monocrystalline silicon, glass, quartz or silicon dioxide.

In an embodiment, a second insulating layer 23b is formed on the second surface 20b of the substrate 20′ in a manner that the adhesive layer 21 is formed on the second insulating layer 23b.

Further, the second surface 20b of the substrate 20′ has a plurality of conductive pads 202 exposed from openings 28 of the adhesive layer 21 and the strengthening member 22 such that a plurality of conductive elements 29 such as solder balls are formed on the conductive pads 202.

According to the present invention, a strengthening member and a semiconductor chip are disposed on opposite sides of a substrate, respectively, to form a sandwich structure, and the CTEs of the strengthening member and the semiconductor chip are less than that of the substrate, thereby effectively preventing warpage from occurring to the semiconductor package.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A substrate structure, comprising:
a substrate having a first surface and a second surface opposite to the first surface; and
a strengthening member bonded to the second surface of the substrate, wherein the strengthening member has a coefficient of thermal expansion (CTE) less than a CTE of the substrate.

2. The substrate structure of claim 1, further comprising an adhesive layer bonded between the strengthening member and the second surface of the substrate.

3. The substrate structure of claim 2, further comprising an insulating layer formed on the second surface of the substrate, wherein the adhesive layer is formed on the insulating layer.

4. The substrate structure of claim 2, wherein the second surface of the substrate has a plurality of conductive pads exposed from a plurality of openings of the adhesive layer and the strengthening member such that a plurality of conductive elements are formed on the conductive pads.

5. The substrate structure of claim 1, wherein the CTE of the strengthening member is less than 10 ppm/.

6. The substrate structure of claim 1, wherein the strengthening member has a thickness between 50 and 250 um.

7. The substrate structure of claim 1, wherein the strengthening member is made of one selected from the group consisting of graphite, graphene, polycrystalline silicon, monocrystalline silicon, glass, quartz and silicon dioxide.

8. A semiconductor package, comprising:
a substrate having a first surface and a second surface opposite to the first surface;
a strengthening member bonded to the second surface of the substrate, wherein the strengthening member has a CTE less than a CTE of the substrate;
an interposer disposed on the first surface of the substrate; and
a semiconductor chip disposed on the interposer.

9. A method of fabricating a substrate structure, comprising:
providing a substrate having a first surface and a second surface opposite to the first surface; and
bonding a strengthening member to the second surface of the substrate, wherein the strengthening member has a CTE less than a CTE of the substrate.

10. The method of claim 9, wherein the strengthening member is bonded to the second surface of the substrate through an adhesive layer.

11. The method of claim 10, further comprising an insulating layer formed on the second surface of the substrate, wherein the adhesive layer is formed on the insulating layer.

12. The method of claim 9, wherein the CTE of the strengthening member is less than 10 ppm/.

13. The method of claim 9, wherein the strengthening member has a thickness between 50 and 250 um.

14. The method of claim 9, wherein the strengthening member is made of one selected from the group consisting of graphite, graphene, polycrystalline silicon, monocrystalline silicon, glass, quartz and silicon dioxide.

15. A method of fabricating a semiconductor package, comprising:
providing a substrate having a first surface and a second surface opposite to the first surface;
bonding a strengthening member to the second surface of the substrate, wherein the strengthening member has a CTE less than a CTE of the substrate; and
disposing a semiconductor element on the first surface of the substrate and electrically connecting the semiconductor element and the substrate.

16. The method of claim 15, wherein the semiconductor element comprises:
an interposer;
a semiconductor chip disposed on the interposer; and
a plurality of conductive elements disposed between the interposer and the semiconductor chip and electrically connected to the interposer and the semiconductor chip.

17. The method of claim 15, wherein the second surface of the substrate has a plurality of conductive pads, and the method further comprises:
removing a portion of the strengthening member to form a plurality of openings exposing the conductive pads; and
forming a plurality of conductive elements on the conductive pads.
